(19) United States
(12) Patent Application Publication
(10) Pub. No.: US 2013/0056058 A1
(43) Pub. Date: Mar. 7, 2013

(54) CONTACT SOLAR CELL AND METHOD FOR PRODUCING SAME

(71) Applicant: Harry Wirth, Merzhausen (DE)

(72) Inventor: Harry Wirth, Merzhausen (DE)

(73) Assignee: Fraunhofer-Gesellschaft zur Forderung der Angewandten Forschung E.V,, Munchen (DE)

(21) Appl. No.: 13/520,436

(22) PCT Filed: Jan. 4, 2011
(86) PCT No.: PCT/EP2011/000014

§ 371 Date: Nov. 19, 2012

(30) Foreign Application Priority Data
Jan. 4, 2010 (DE) 1020100040045

(51) Int. Cl. H01L 31/0224; H01L 31/18

(52) U.S. Cl. 136/256; 438/98; 257/E31.124

(57) ABSTRACT

The present invention relates to a contacted solar cell which has contact places on the front- and rear-side for electrical contacting of the solar cell. The current produced by the solar cells is tapped across the solar cells by means of a conductor fitted on the front- or rear-side, the contact places of the solar cell being arranged, according to the invention, on the front- or rear-side such that, in projection on the front-face of the solar cell, they do not come to coincide.

The present invention relates to a contacted solar cell which has contact places on the front- and rear-side for electrical contacting of the solar cell. The current produced by the solar cells is tapped across the solar cells by means of a conductor fitted on the front- or rear-side, the contact places of the solar cell being arranged, according to the invention, on the front- or rear-side such that, in projection on the front-face of the solar cell, they do not come to coincide.

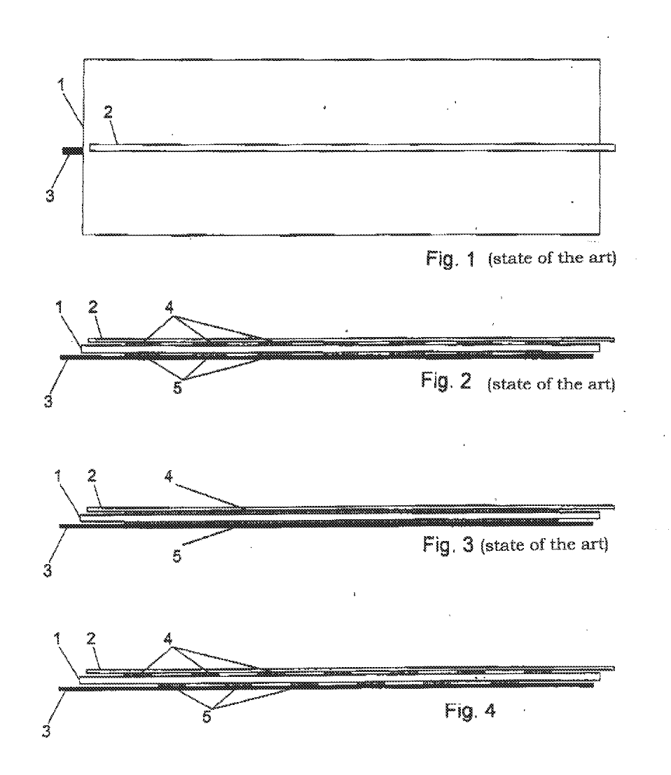

Normal solar cells 1 are connected with flat wire 2, 3 in order to transport the electrical current away (see e.g. FIG. 1). The wires are soldered onto specially configured contact places of the cell. The linearly disposed, generally continuously configured contact places of the opposite poles are disposed one above the other so that soldered connections 4, 5 can be produced at the same time on both sides of the cell, which soldered connections are disposed coinciding one above the other in projection on the front-side of the solar cell (see FIG. 2).

Because of differences in coefficients of thermal expansion when temperature changes occur, in particular during cooling after solidification of the solder, stresses arise between the conductor- and the cell material. These stresses are particularly problematic in the case of lead-free solders with melting temperatures around 220° C.

According to other embodiments according to the state of the art, the pre-soldered flat wire or the cell can also be connected with flux over the entire contact length. The heat supply for the soldering process is achieved by contact, radiation, hot air, induction or other common methods. It is effected from one side of the cell, soldered connections being produced at the same time on both sides of the cell. These connections are formed at points (FIG. 2) or continuously (FIG. 3), but in all cases they are situated one above the other (U.S. Pat. No. 4,562,637).

As a consequence, the cell at the joining places experiences stresses from both sides which are added together. Hence the risk of material failure at this place during processing or during use of the system increases.

In order to reduce the stress, stress-relieving elements between the cells have been proposed (DE 43 30 282 C2, DE 39 42 031 C1, DE 41 04 160 A1) which do not however reduce the stresses inside a cell and signify increased complexity.

Starting from the state of the art, it was therefore the object of the present invention to provide contacted solar cells with which minimisation of the mechanical stress caused by the contacting of the solar cell is made possible. This object is achieved, with respect to the contacted solar cell, by the features of patent claim 1, with respect to the method for the production of such solar cells by the features of patent claim 7, the respective dependent patent claims respectively representing advantageous developments.

According to the invention, a contacted solar cell having a front-side, which has at least a first contact place, and also a rear-side, which has at least a second contact place, is provided, the contact places of the front- and of the rear-side respectively being connected in an electrically conducting manner to at least a first or at least a second conductor, the faces of the contact places not intersecting in projection of the solar cell on the front-side.

The proposed solution hence provides an offset arrangement of connections at points on both sides (see e.g. FIG. 4). In this way, the stresses are distributed over the length of the contact place and superimposition from both sides of the cell is avoided.

Surprisingly, it was able to be established that, by means of such an arrangement of the contact places on the solar cell and also by means of a connection of the respective conductor structures to the contact places on each side, a significant reduction in stress of the mechanical stress resulting from contacting with the conductors can be achieved.

By reducing the stresses, the clearance during production of solar modules is enlarged. Lead-free solders or larger cross-sections of the cell connectors can be used.

In a preferred embodiment, the solar cell is thereby configured such that the front- and the rear-side respectively has at least two contact places, preferably respectively 2 to 20, further preferred respectively 6 to 14 contact places.

It is likewise advantageous if the contact places are disposed linearly.

Advantageous conductors, which can be used for contacting the contact places of the solar cell, are thereby flat wires, both the conductor used on the front-side and/or on the rear-side thereby advantageously being flat wires.

Furthermore, it is advantageous if in projection of the solar cell on the front-side, the conductors disposed on the front- and rear-side of the solar cell coincide respectively in pairs. In this embodiment, it is hence provided that both the conductor disposed on the front-side and the one on the rear-side (or in the case of a plurality of conductors disposed respectively on the front- and rear-side, these respectively in pairs) coincide in the projection direction on the solar cell surface of the front-side, the contact places with which the conductors are fixed on the solar cell however not thereby coinciding. The result thereby is mutual contacting of the respective conductors on the front- or rear-side.

The contact regions thereby preferably have respectively an area of 2 to 30 mm², preferably of 4 to 20 mm², particularly preferred 6 to 18 mm².

According to the invention, a method for the production of a contacted solar cell is likewise provided, in which at least a first conductor is connected in an electrically conducting manner at at least one contact place which is situated on the front-side of the solar cell, and at least a second conductor is connected in an electrically conducting manner at at least one contact place which is situated on the rear-side of the solar cell, the faces of the contact places not intersecting in projection of the solar cell on the front-side.

Preferably, the electrically conducting connection, i.e. the contacting of the solar cell, or the production of the connection of the conductor and of the contact place is thereby effected by soldering of the conductor to the contact place. This advantageous method relates to both the production of the contacts on the front- and the rear-side. Other known connection methods, such as welding, gluing or bonding, are likewise included by the invention.

Furthermore, it is thereby advantageous if the contacting of the at least one first conductor to the at least one contact place and of the at least one second conductor to the at least one contact place is effected simultaneously in one operating step. In the case where such a simultaneous contacting of the conductor on the front-side and of the conductor on the rear-side is effected, it is thereby further advantageous if the heat supply which is required for the soldering is still effected from one side of the solar cell, it being ensured that connections are produced only respectively on one side of the cell.

Furthermore, it is thereby advantageous that the contacting in portions is effected in the soldering method by corresponding covering with flux in portions, which is effected before soldering, and subsequent soldering.

Possible embodiments of a solar cell according to the invention or of a method for production thereof are indicated subsequently without however restricting the invention to the special embodiments.

One possibility for selective production of connection places is the selective application of flux on cell or cell connector. Soldered connections are thus produced only at the places which have been covered with flux. Places without flux transfer the heat to the rear-side of the cell without forming a mechanical connection after solidification of the solder.

Alternatively, solder can also be applied selectively on cell or cell connector. Furthermore, it is also conceivable to equip the cell with offset contact places, corresponding to the arrangement of the contact places 4, 5 in FIG. 4.

The present invention is explained in more detail with reference to the subsequently attached Figures without however being understood to be restrictive in accordance with the represented Figures.

FIG. 1 shows an arrangement, known from the state of the art, of two conductors 2 and 3 which are disposed on the front-side and also on the rear-side of a solar cell 1. It can be detected that both conductors 2 and 3 are disposed coinciding in the projection direction on the front-side of the solar cell (this is the side on which the conductor structure 2 is disposed), i.e. are situated one above the other in the projection direction.

FIG. 2 shows a type of contacting of the two conductors 2 and 3 on the solar cell 1 which is known from the state of the art. The conductors are thereby disposed in projection on the front-side of the solar cell as represented in FIG. 1, i.e. situated one above the other in projection. The contactings 4 of the conductor 2 or 5, fitted on the front-side of the solar cell 1, of the conductor 3 disposed on the rear-side of the solar cell 1 are thereby situated likewise one above the other in projection. Stresses which arise for example during soldering of the solar cell due to the different coefficients of thermal expansion of the materials which are used can lead to material failure.

An alternative manner for contacting the conductors 2 and 3 on the solar cell 1, which is known from the state of the art, is represented in FIG. 3, the contactings 4 and 5 are thereby configured continuously quasi across the entire solar cell. Here also, the mechanical stresses which arise due to soldering of the strip conductors 2 and 3 on the solar cell 1 are conserved and cannot be effectively reduced.

By means of the type of contacting according to the invention, as represented in FIG. 4, the mechanical stresses are reduced by far. The contacting via the contact places 4 and 5 is thereby effected such that these contact places respectively are disposed offset relative to each other, i.e. do not coincide or do not intersect in projection on the front-side of the solar cell. The strip conductors 2 and 3 are thereby represented as disposed in FIG. 1, i.e. come to coincide in projection on the front-side of the solar cell.

1. A contacted solar cell having a front-side, which has at least a first contact place, and also a rear-side, which has at least a second contact place, the contact places of the front- and of the rear-side respectively being connected in an electrically conducting manner to at least a first or at least a second conductor,
wherein
the faces of the contact places do not intersect in projection of the solar cell on the front-side.

2. The solar cell according to claim 1, wherein the front- and the rear-side respectively has at least two contact places.

3. The solar cell according to claim 1, wherein the contact places are disposed linearly.

4. The solar cell according to claim 1, wherein the first conductor and/or the second conductor is a flat wire.

5. The solar cell according to claim 1, wherein, in projection of the solar cell on the front-side, the conductors coincide respectively in pairs.

6. The solar cell according to claim 1, wherein the contact regions have respectively an area of 2 to 30 mm².

7. A method for the production of a contacted solar cell, in which at least a first conductor is connected in an electrically conducting manner at at least one contact place which is situated on the front-side of the solar cell, and at least a second conductor is connected in an electrically conducting manner at at least one contact place which is situated on the rear-side of the solar cell,
wherein
the faces of the contact places do not intersect in projection of solar cell on the front-side.

8. The method according to claim 7, wherein the at least first conductor and/or the at least second conductor is soldered to the at least one contact place which is situated on the front-side of the solar cell and/or to the at least one contact place which is situated on the rear-side of the solar cell.

9. The method according to claim 7, wherein the contacting of the at least one first conductor to the at least one contact place which is situated on the front-side of the solar cell and of the at least one second conductor to the at least one contact place place which is situated on the rear-side of the solar cell is effected simultaneously in one operating step.

10. The method according to claim 7, wherein the contacting in portions is effected in the soldering method by corresponding covering with flux in portions, which is effected before soldering, and subsequent soldering.

11. The method according to claim 7, wherein the contacting in portions is effected in the connection method by a correspondingly offset arrangement of connectable material on the cell.
